(19) United States
(12) Patent Application Publication
(10) Pub. No.: US 2026/0138869 A1
(43) Pub. Date: May 21, 2026

(54) Method for singulating a wafer and suitable device

(71) Applicants: Robert Bosch GmbH, Stuttgart (DE); Carl Zeiss SMT GmbH, Oberkochen (DE)

(72) Inventors: Ralf Noltemeyer, Herrenberg (DE); Arnd Kaelberer, Schlierbach (DE); Heiko Stahl, Reutlingen (DE); Tobias Henn, Stuttgart (DE); Jan Stiedl, Pliezhausen (DE)

(21) Appl. No.: 19/109,942

(22) PCT Filed: Aug. 28, 2023
(86) PCT No.: PCT/EP2023/073562

§ 371 Date: Mar. 7, 2025

(30) Foreign Application Priority Data
Sep. 9, 2022 (DE) 10 2022 209 447.6

(51) Int. Cl. B81C 1/00

(52) U.S. Cl. CPC B81C 1/00896; B81C 1/00063; B81C 1/00531; B81C 2201/056

(57) ABSTRACT

A method for singulating a wafer having a first surface and a second surface situated opposite the first surface is disclosed. The method includes the following steps: contacting the wafer with a protective device having one or a plurality of carrying structures such that the first surface of the wafer is in contact with the plurality of carrying structures, singulating the wafer that is in contact with the protective device into a plurality of chips, and removing the chips from the wafer that is in contact with the protective device. Furthermore, a protective device having one or a plurality of carrying structures for temporarily carrying a wafer is disclosed. The protective device is configured to be used in the method disclosed herein.

The present invention is concerned with the field of producing semiconductor chips from wafers, in particular for microelectromechanical devices, and relates to a method for singulating a wafer and to a protective device for temporarily carrying a wafer for use in such a method.

### PRIOR ART

Devices comprising microelectromechanical systems (MEMS), for example micromirror arrays or micromirror actuators, are used nowadays in a multiplicity of devices, for example in smartphones, projectors, head-up displays, barcode readers, mask exposure units in semiconductor fabrication, and microscopes. Corresponding micromirror arrays are known for example from the documents DE 10 2013 208 446 A1, EP 0 877 272 A1 and WO 2010/049076 A2. During the production of the individual microelectromechanical systems on the basis of wafers, constant protection of the microelectromechanical structures of these systems must be ensured in order to avoid undesired damage. Particularly critical steps here are for example soldering or sintering processes and in particular also the singulation of the wafers into individual chips (dies), since these can easily lead to damage and/or contamination of the microelectromechanical structures. For this reason, the sensitive structures are typically protected temporarily by suitable protective structures, which however greatly reduce the fill factor of the end product, i.e. the chips produced.

### Disclosure of the Invention

According to the invention, a method for singulating a wafer and a protective device for temporarily carrying a wafer for use in a method according to the invention are proposed.

In accordance with a first aspect of the invention, a method for singulating a semiconductor wafer (also referred to as wafer for short in the context of this invention), in particular a silicon wafer, having a first and a second surface is proposed, wherein the second surface is situated opposite the first surface. The first and second surfaces are thus the two different main surfaces of the wafer. In this case, the method comprises contacting the wafer with a protective device, for example positioning the wafer on the protective device, wherein the protective device has one or a plurality of carrying structures. In this case, the wafer is contacted with the protective device such that the first surface of the wafer is in contact with the one or the plurality of carrying structures. In this case, for example, the protective device can serve for temporarily carrying the wafer or can be temporarily positioned thereon. The wafer is thus typically placed onto the protective device or the protective device is positioned on the wafer.

During or after the contacting, bonding the wafer to the protective device can be carried out, for example by means of sintering or eutectic bonding, in order to avoid undesired movements, for example displacements, of wafer and protective device with respect to one another. The handling of wafer and protective device is thus facilitated and joint movement and/or rotation of the protective device together with the wafer is thus made possible. Alternatively, it is also possible to dispense with such bonding and, optionally, it is also possible to use a fixing device for temporarily fixing the contact between protective device and wafer. Dispensing with bonding allows the protective device, if appropriate after cleaning, to be reused for further wafers.

After contacting the wafer with the protective device, optionally once further steps for processing the wafer have been carried out, such as, for example, etching of so-called sacrificial regions in semiconductor layers of the wafer (sacrificial layer etching), for example for freeing structures for a MEMS (microelectromechanical system), and/or wafer bonding, for example eutectic bonding, of a second wafer to the wafer, singulating the wafer (in the case of wafer bonding having been effected, together with singulating the bonded second wafer, i.e. the entire coupled wafer) into a plurality of semiconductor chips (also referred to as chip for short in the context of this invention) is effected. Sacrificial layer etching can be effected for example by means of chlorine trifluoride (CIF₃), chlorine fluoride (CIF), chlorine pentafluoride (CIF₅), bromine trifluoride (BrF₃), bromine pentafluoride (BrF₅), iodine pentafluoride (IF₅), iodine heptafluoride (IF₇), sulphur tetrafluoride (SF₄), xenon difluoride (XeF₂) or similar substances. The chips are subsequently removed from the wafer, which is still in contact with the protective device. In this case, the steps of singulating and removing can coincide, i.e. take place simultaneously. Singulating the wafer can thus take place before removing the chips from the wafer, but can also be effected together with removing the chips.

In this case, the protective device serves for protecting parts of the wafer during critical steps such as, for example, bonding, for example wafer bonding (such as eutectic bonding) of a further wafer to the wafer or bonding of further chips to the wafer, in particular by means of soldering and/or sintering and/or eutectic bonding, wafer testing and/or singulating during this temporary carrying by the protective device. The wafer is preferably to be contacted with the protective device, for example positioned with respect thereto, such that structures of the wafer that are to be protected do not come into contact with the one or the plurality of carrying structures of the protective device. Furthermore, the wafer is preferably to be contacted with the protective device such that the structures to be protected are protected by the protective device as well as possible for the processing steps that follow.

After contacting the wafer with the protective device and before singulating the wafer, forming a gap structure which encloses individual chips, locally perforates (penetrates through) the wafer (does not form closed shapes such as rectangles) and has a plurality of gaps in the wafer is preferably effected. The subsequent singulating is effected at least partly along these plurality of gaps. The singulating can be effected for example by breaking and/or cutting by means of a laser (laser cutting) and/or an etching method. A chip to be detached from the wafer is partially separated from the rest of the wafer (remainder of the wafer) by this process of forming the gap structure. The gap structure is typically formed in such a way that webs (isolated connections) connect the individual chips to the remainder of the wafer. What is achieved thereby is that the chip can easily be detached from the wafer later, for example when removing the chip from the protective device. In such a case, removing the chip is thus carried out in parallel with the singulating; for example by simply breaking the webs, the chip is thus detached from the wafer. By using a suitable method for laser cutting, it is also possible to vaporize the webs. This has the advantage that the webs are completely removed, without giving rise to uncontrolled fragments of the webs.

Alternatively or additionally, a trench structure which encloses the individual chips and has one or a plurality of trenches can also be formed on the first surface and/or the second surface of the wafer. By means of the trench structure, the wafer is thinned in a targeted manner, i.e. provided with one or a plurality of trenches. Singulating the wafer is then effected at least partly along the one or the plurality of trenches. In the context of this invention, a trench structure having one or a plurality of trenches on a surface of a wafer means a structure composed of one or a plurality of trenches in a wafer in such a way that the trench(es) is (are) open towards the surface. The trench(es) of a trench structure typically enclose(s) chips to be detached from the rest of the wafer in the context of the singulating. In the case of a trench structure, too, the advantage resides in simplifying singulating, for example by breaking out the chip from the rest of the wafer. A trench structure which encloses the individual chips can also comprise non-interconnected trenches, i.e. can for example consist of a multiplicity of individual trenches which enclose chips and which need not be interconnected. The totality of these trenches is referred to as trench structure in the context of this invention.

Alternatively or additionally, forming a gap structure which encloses individual chips and has one or a plurality of gaps in the wafer can be effected. Here the singulating can be effected at least partly by forming the gap structure. If all the chips on a wafer are enclosed by the gap structure, the wafer is completely singulated by the latter. Separate singulation is not necessary. As in the case of a trench structure, a gap structure can also consist of non-interconnected cutouts; for example, around individual chips, it is possible to route a respective cutout in the form of a gap enclosing this chip. The totality of these gaps is referred to as gap structure in the context of this invention. A locally perforating gap structure is accordingly a gap structure in which the gaps do not form closed shapes. Singulating the wafer by forming a gap structure in the wafer is particularly advantageous since, in this case, the release of particles that could lead to the contamination of sensitive structures on the wafer can be completely avoided.

In the context of this invention, a gap structure should be understood to mean one or a plurality of cutouts of the wafer which completely penetrate through the latter in the vertical direction. In contrast thereto, a trench structure means one or a plurality of recesses which do not extend over the full thickness of a wafer.

Singulating a wafer along a locally perforating gap structure means singulating in such a way that a plurality of cutouts of the gap structure are utilized for detecting a chip from the rest of the wafer, which takes place by way of destroying, for example breaking, connections (for example in the form of webs) that still exist between the chip and the rest of the wafer. Gaps of gap structures and trenches of trench structures can differ from simple gaps and trenches running perpendicularly through the wafer, i.e. rectangular cutouts and recesses; for example, the use of undercuts is conceivable. In particular, the gaps and the trenches can be fashioned such that holding structures are shaped at least locally, which continue to fix the individual chips in the wafer after the singulation thereof, i.e. restrict the movement of the individual chips after singulation, for example in order to prevent the individual chips from inadvertently falling out of the wafer during a movement of the wafer.

In one particular configuration of the method according to the invention, forming the gaps and/or the trenches and thus also the gap structure and/or the locally perforating gap structure and/or the trench structure is effected by means of an etching process. In this case, for example, deep reactive ion etching (DRIE) can be used as an etching method. Furthermore, forming the gap structures and/or the trench structure can be carried out before contacting the wafer with the protective device. Preferably, forming the gap structures and/or the trench structure is effected after contacting the wafer with the protective device and also preferably after possible bonding of the wafer to the protective device in order to utilize the protective function of the protective device already for this method step. Such an etching process is preferably combined with an etching process for etching structures of the chips, for example sacrificial layer etching, such that one method step includes both forming the gap structure and/or the locally perforating gap structure and/or the trench structure and carrying out sacrificial layer etching. The singulating can finally be carried out for example using an etching method, a laser cutting method and/or a breaking method. Here, too, an appropriate etching method is deep reactive ion etching (DRIE), but also etching by means of xenon difluoride (XeF₂).

The method according to the invention is usable particularly advantageously in the fabrication of microelectromechanical systems. This is the case, in particular, if the wafer has open structures for microelectromechanical systems (MEMS structures). In such a case, the wafer is contacted and preferably bonded with the protective device such that the one or the plurality of carrying structures do not touch the open MEMS structures. If the open MEMS structures are open towards the first surface of the wafer, further steps in the context of processing the wafer can then be carried out on the opposite second surface of the wafer, for example soldering, sintering, wafer bonding, bonding of further chips, wafer testing and/or finally singulating the wafer, without the first surface protected by the protective device being jeopardized in the process. The method is usable very particularly advantageously if the open MEMS structures also comprise MEMS structures for a micromirror array, since such structures are particularly sensitive.

In one particularly preferred embodiment of the method according to the invention, the wafer has holding structures, and/or after contacting with the protective device and before singulating the wafer, forming holding structures in the wafer is effected, wherein the holding structures are configured to restrict possible movements of the chips after singulating in at least one direction. By way of example, the holding structures can prevent the individual chips from falling out of and/or falling down from the wafer after the singulating and can instead hold the individual chips in the rest of the wafer and thus the protective device. A holding structure can be manifested for example by means of suitable cutouts and/or recesses with undercuts in the wafer. A holding structure is advantageously arranged at an edge of a chip to be released by the singulation and ensures that the chip interlocks with the rest of the wafer after the singulation has been carried out, which prevents free movement of the chip in a direction perpendicular to the first surface of the wafer. This makes it possible to prevent the chips from falling down, for example, if the wafer is arranged horizontally (i.e. perpendicularly to the direction of gravity) on the protective device. It is also conceivable for holding structures to be implemented by means of gap structures which are suitable for preventing undesired movement of the chips of the wafer in both directions perpendicular to the first surface of the wafer after the singulating. Holding structures are advantageous, in particular, if the wafer is rotated and/or moved together with the protective device. After singulating and before removing the chips, it can be advantageous, for the purpose of removing the chips, to rotate the wafer together with the protective device by an angle of 170°to 190°,preferably 180°, about an axis parallel to the first surface of the wafer, wherein the holding structures are manifested for this purpose such that the chips remain in the wafer during the rotating. For the rotating, the protective device is connected to the wafer releasably or non-releasably, for example by means of bonding and/or a fixing device for temporarily fixing the wafer. Gap structures which are formed for singulating the wafer are particularly advantageously combinable with such rotating if they comprise suitable holding structures. For this purpose, gap structures for example can have a groove at suitable locations on one side of a gap of the gap structure, said groove running parallel to the first surface of the wafer, and can have a projection at the same locations on the opposite side of the gap, for example in the form of a rail or a projection, in such a way that this rail or this projection is received by the groove, with a spatial distance remaining between the two elements. The combination of groove and projection thus provides a loose connection between an individual chip and the rest of the wafer. In this case, the groove can be implemented in the chip, and the projection accordingly belongs to the rest of the wafer. However, an opposite arrangement (groove in the rest of the wafer, projection associated with chip) is likewise conceivable. The rest of the wafer can be fashioned by means of one or a plurality of suitable recesses such that the projection or the rail can be displaced away from the chip. As a result, said loose connection can be separated. By way of such a mechanism, therefore, after the singulation, chips can first be held in the wafer and afterwards be released in a targeted manner in the sense that they are removable from the wafer.

Rotating the wafer by 170° to 190° can be advantageous particularly if the protective device is arranged above the wafer before the rotating, that is to say in particular in the case where the contacting of wafer and protective device is effected by the protective device being applied to the wafer from above. In the context of this invention, the terms “above” and “from above” relate to the direction of gravity: One object is situated “above” another object if it is arranged counter to the direction of gravity in relation to the other object. Accordingly, “from above” means that something is effected in the direction of gravity; “upwards” means counter to the direction of gravity. The terms “below”, “from below” and “downwards” should be understood equivalently. In the case described, the carrying structures of the protective device carry the wafer after the rotating, and the rotating is effected about an axis perpendicular to the direction of gravity. The chips can be removed from the wafer after the rotating. Such a procedure is particularly preferred if, for specific process steps, it is advantageous for the first surface of the wafer protected by the protective device to be oriented upwards, and/or if the protective device is situated above the wafer. By way of example, it may be the case that for etching purposes an etching gas is supplied via openings in a region of an outer wall of the protective device. In this case, it is typically advantageous for such openings to be distributed as homogeneously as possible and over the largest possible area. If regions of the outer wall are intended to function as a base for positioning the protective device on a repository, there is the risk of openings present in these regions being blocked and gas supply not being possible. Possible positions for openings for gas supply are thus limited. Such a limitation can be avoided for example by carrying out the etching process with the protective device being oriented with the wafer such that the protective device is arranged above the wafer. There is no risk of openings for supplying an etching gas being blocked; the positions of such openings can be chosen freely. Since, after singulation, the chips have to be removed in a direction which is not blocked by the protective device, it is typically necessary for the wafer to be rotated, however, for removal purposes. After the etching process has been carried out, the wafer is thus rotated together with the protective device preferably by 180° about an axis parallel to the first surface (i.e. about an axis perpendicular to the direction of gravity) and is positioned on a repository surface for the purpose of removing the chips.

Any desired steps in the context of the production method are conceivable before singulating the wafer. By way of example, in order to prepare the wafer for further method steps in the production process after contacting the wafer with the protective device, a sintering paste and/or a solder can be applied to the second surface of the wafer. Moreover, for example, wafer bonding, for example by means of eutectic bonding, of a second wafer can be effected. Testing of the wafer in regard to its functionality (wafer testing) and/or of parts of the wafer can also take place before the singulating while the wafer is in contact with the protective device.

In accordance with a second aspect of the invention, a protective device having one or a plurality of carrying structures for temporarily carrying a wafer on the protective device and/or for temporarily carrying the protective device on the wafer is proposed, wherein the protective device is configured to be used in a method according to the invention. Typically, a wafer to be protected is placed with a first surface to be protected facing downwards onto the one or the plurality of carrying structures of such a protective device, wherein the first surface of the wafer is arranged in a manner oriented perpendicularly to the direction of gravity.

Moreover, a protective device can also be embodied such that it can be positioned on the wafer, i.e. is typically applied to the wafer from above, wherein the first surface to be protected of the wafer is oriented upwards. In this case, the carrying structures carry the protective device on the wafer.

A protective device according to the invention can substantially consist of silicon, for example, which is provided with a passivation layer affording protection against an etching gas used. The use of silicon has the advantage that, in the event of temperature changes, the protective device expands and contracts to the same extent as a wafer which is in contact with it and which likewise consists of silicon. Consequently, displacements and undesirable mechanical stresses between wafer and protective device do not occur. The passivation layer can consist of silicon dioxide and/or silicon nitride, for example. Alternatively, a protective device according to the invention can also consist of other materials or material compositions, for example a metal and/or a metal alloy, for example a steel, and/or a ceramic.

Preferably, the protective device is at least partly shielded from an environment of the protective device by one or a plurality of outer walls in order to prevent undesirable substances such as foreign particles, for example, from reaching the first surface to be protected of the wafer and in particular structures to be protected that are situated there. By way of example, the protective device can have one or a plurality of side walls and a base. An outer wall of the protective device can have one or a plurality of openings for gas supply. Preferably, the one or the plurality of outer walls with a wafer positioned on the protective device enclose an interior. Apart from optional openings for gas supply, the one or the plurality of outer walls of the protective device are preferably embodied in gas-tight fashion or have only low permeability. The same preferably also applies to connections between an outer wall of the protective device and the wafer, and to connections between two outer walls of the protective device. One or a plurality of openings for gas supply can be positioned for example in an outer wall opposite to a wafer (rear-side outer wall) and/or a lateral outer wall (side wall) and are preferably configured to supply an etching gas to the interior. By supplying a gas and/or positioning such a protective device in a corresponding gas atmosphere, it is possible to alter a gas pressure in the interior of the protective device. Preferably, the protective device has a multiplicity of openings for gas supply which are embodied as holes, which are dimensioned such that undesirable particles (foreign particles) originating from outside the protective device, starting from a specific particle size, are completely unable, or unable with a sufficiently high probability, to pass into the interior of the protective device. The holes thus have a filter function. The holes can for example be dimensioned, for example by way of a correspondingly chosen diameter, such that they do not permit any passage whatsoever of foreign particles starting from a particle size of 5 μm, of 2 μm, of 1 μm, of 0.5 μm, of 0.2 μm or of 0.1 μm, or permit passage thereof only with a tolerable probability. The holes can thus be used to supply etching gas to the interior of the protective device in order to carry out an etching process on the wafer positioned on the protective device, without the first surface of the wafer being contaminated with externally originating foreign particles in the process. Preferably, the rear-side outer wall of the protective device, i.e. the rear side thereof, is designed to be planar, such that it allows particularly simple handling and can be used as a base on which the protective device together with the wafer can be stood for example for a wafer test and/or for removing the chips after singulation.

The one or the plurality of carrying structures of the protective device can have for example the form of continuous or interrupted walls, arches, lattices, struts and/or supports, which are preferably arranged in a grid. Such carrying structures preferably can run at least partly parallel and/or along gaps and/or trenches of a gap structure and/or trench structure-formed or to be formed for the purpose of singulating the wafer-in the wafer to be carried and can thereby enclose the structures to be protected according to the chips and in the case of continuous walls, for example, can afford further protection for these structures. When contacting a wafer with a protective device according to the invention, for example when positioning the wafer on the protective device, the wafer is preferably arranged such that the carrying structures do not touch particularly sensitive regions of the wafer. In order to achieve this and/or to simplify method steps that are carried out automatically, a protective device can be fashioned such that a wafer can be contacted with the protective device only in a defined orientation. By way of example, a notch or a flat of the wafer in interplay with a corresponding shape of the protective device can be utilized for this purpose.

In one particularly preferred configuration of the protective device according to the invention, the protective device comprises a fixing device for fixing the wafer during temporary carrying of the wafer. The task of such a fixing device is thus to prevent undesired movements of the wafer. For this purpose, the fixing device preferably has one or a plurality of fixing elements for preventing an undesired lateral displacement of the wafer. Such a fixing element can consist of a frame enclosing the wafer, for example. Such a frame can at the same time also be embodied such that it seals the protective device laterally towards the outside in order to protect the first surface of the wafer even better. In such a case, the frame thus functions simultaneously as an outer wall. A further preferred possibility for preventing undesired movements of the wafer, which possibility can be used as an alternative or in addition to a fixing device, is bonding the wafer to the protective device.

### Advantages of the Invention

The invention discloses a method and a device, in the context of a production process of semiconductor chips, for protecting particularly sensitive structures of the corresponding wafers against damage and/or contamination resulting from foreign particles, for example. In particular, possibilities are disclosed for protecting the chips during the singulation of the wafer as well. In this case, a protective device according to the invention supports itself on regions outside the chips, as a result of which the fill factor on the individual chips is not adversely affected. A protective device according to the invention can thus protect structures on the wafer, without additional structures on the wafer necessarily having to be produced for such a protective device.

A protective device according to the invention can be optimized for singulation of the wafer by means of etching, breaking and/or using a laser. This makes it possible to improve the fill factor of the individual chips and of the wafer since there is no need to provide wide sawing streets on the wafer for sawing and the methods mentioned are more precise than sawing. Particularly if use is made of an etching method and/or laser cutting, undesired particle contamination does not occur.

Although a wafer must preferably be contacted with a protective device according to the invention such that the one or the plurality of carrying structures of the protective device are in contact with the wafer only outside the regions to be protected, the fill factor of the wafer is not impaired as a result since corresponding regions typically also have to be kept available for singulating and for stabilizing the wafer.

### BRIEF DESCRIPTION OF THE DRAWINGS

Embodiments of the invention are explained in more detail with reference to the drawings and the following description.

In the figures:

FIG. 1A shows a schematic illustration of a detail from an exemplary protective device according to the invention with a first wafer;

FIG. 1B shows a schematic illustration of a detail from an exemplary protective device according to the invention with a second wafer;

FIG. 1C shows a schematic illustration of a detail from the exemplary protective device according to the invention from FIG. 1B with the second wafer from FIG. 1B after singulation;

FIG. 2 shows a schematic illustration of a wafer in a protective device according to the invention in a plan view and a perspective view;

FIGS. 3A, 3B, 3C show three schematic illustrations of a detail from a further exemplary protective device according to the invention with a third wafer at different points in time; and

FIG. 4 shows, in schematic form as a flow diagram, a method according to the invention for singulating a wafer using a protective device according to the invention.

### EMBODIMENTS OF THE INVENTION

In the following description of the embodiments of the invention, identical or similar elements are designated with the same reference signs, a repeated description of these elements in individual cases being omitted. The figures illustrate the subject matter of the invention only schematically.

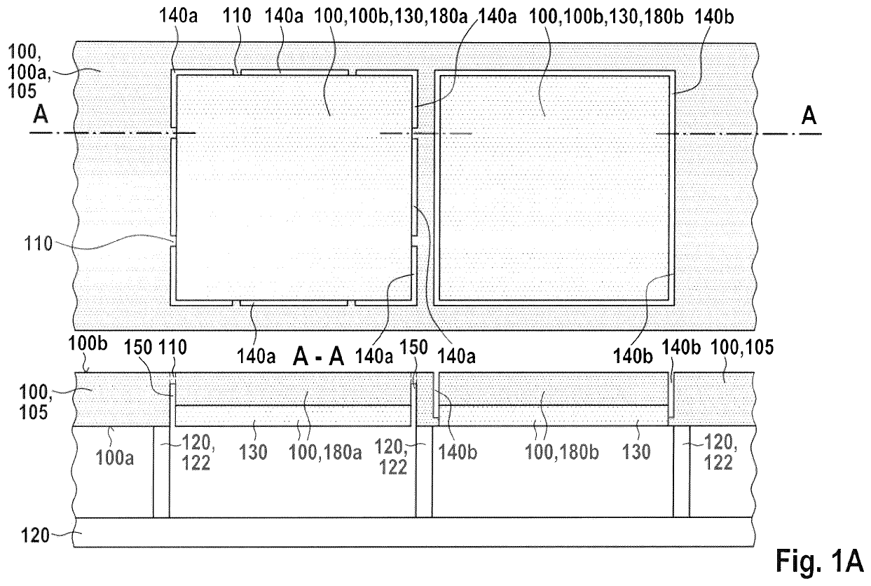

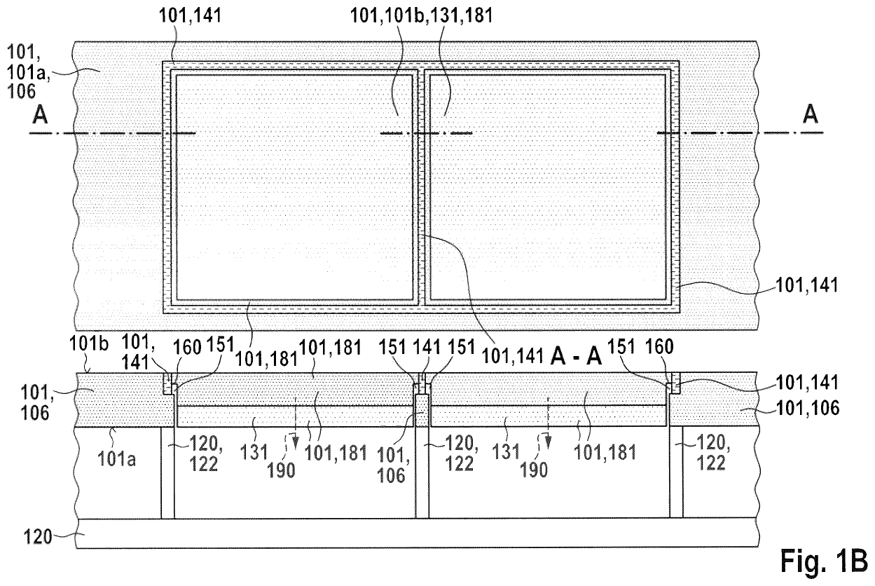

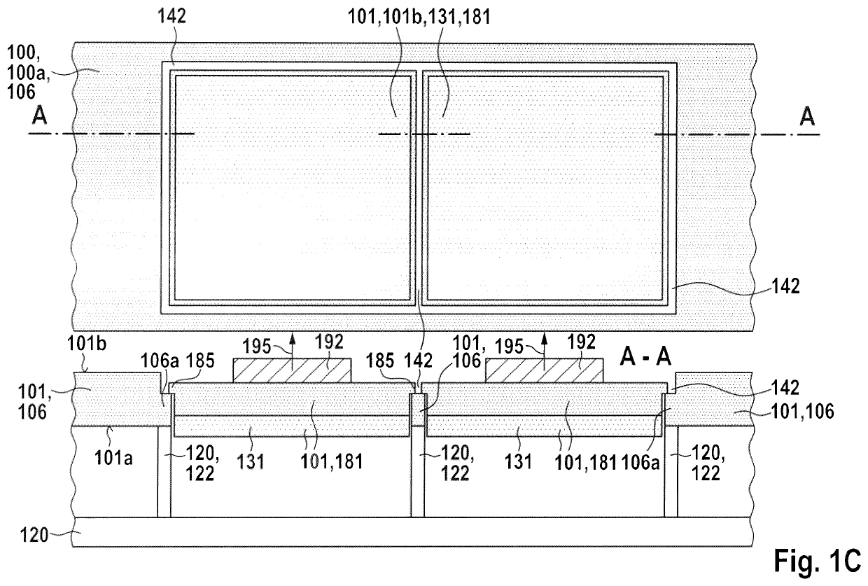

FIG. 1A shows a schematic illustration of a detail from an exemplary wafer 100 having a first surface 100a and a second surface 100b (upper subfigure), which wafer is situated on an exemplary protective device 120 according to the invention (only illustrated in the lower subfigure), the lower subfigure showing the protective device 120 in a surface view and likewise purely schematically. In this case, the lower subfigure illustrates the plane A identified by a dashed line in the upper subfigure. The upper subfigure shows a detail from the wafer 100 with a view of the latter's first surface 100a having two open MEMS structures 130, the illustration showing two chips 180a, 180b—to be produced by singulation of the wafer 100—of MEMS systems, which have said MEMS structures 130. The protective device 120 protects the MEMS structures 130.

From the chips to be produced, the left chip 180a is surrounded by a gap structure which locally perforates the wafer, wherein gaps 140a penetrate through the wafer 100 in the vertical direction and webs 110 have been formed as a connection between the chip 180a to be produced and the remainder 105 of the wafer 100. In order to keep the webs 110 as thin as possible and thus to simplify purely mechanical singulation of the wafer 100 by means of breaking, for example, recesses 150 can be provided in the wafer 100, as can be seen in the lower subfigure, which recesses thin the webs 110 in comparison with the chip 180a and the rest of the wafer 105.

As likewise shown in the lower subfigure, the wafer 100 is situated on carrying structures 122 of a protective device 120. The carrying structures 122 can be wall-type elements, for example, which support the wafer 100 from below parallel to the gaps 140a of the gap structure. In this case, the wafer 100 is placed onto the carrying structures 122 such that the first surface 100a having the MEMS structures 130 faces downwards and at the same time the carrying structures 122 only come into contact with insensitive regions of the wafer 100. Consequently, for example by means of carrying structures 122 embodied as continuous walls and/or by means of an outer wall (not depicted) surrounding the protective device 120, the MEMS structures 130 can be protected against foreign particles that possibly arise during further processing steps that are carried out at or proceeding from the first surface 100b of the wafer.

The webs 110 hold the chip 180a shown on the left in its position, such that work processes such as printing of solder and/or sintering pastes, bonding, for example with a further wafer, a wafer test and finally also singulating can still be carried out on the wafer 100. For the purpose of singulating the wafer 100, the webs 110 can be mechanically broken and/or cut apart by means of a laser, for example, preferably directly during removal of the chip 180a from the protective device 120. Webs 110 or residues of the webs 110 that may possibly have remained on the chips 180 after such singulation can be completely removed after singulation if desired in a further step for example mechanically and/or by means of a laser and/or an etching method.

In the case of the second chip 180b on the right in FIG. 1A, a further possibility for simplifying later singulation of the wafer 100 is shown: In this case, in the wafer 100, a trench structure having a trench 140b was formed on the second surface 100b, although a trench structure on the first surface 100a is likewise conceivable. In the case of a trench structure on the first surface 100a it is also conceivable for this to be formed together with sacrificial layer etching (removal of so-called sacrificial regions by means of an etching method) for the purpose of processing the wafer 100, for example for the purpose of freeing the MEMS structures 130. For such a variant, openings can be provided in an outer wall of the protective device 120, through which openings etching gas can be supplied. For the sake of better clarity, the trench 140b is likewise depicted in the upper subfigure in the case of this variant, even if said trench is not visible in a view of the first surface 100a.

In contrast to the variant on the left (chip 180a), targeted manifestation of webs 110 is dispensed with in the case of the right chip 180b. Instead, the wafer 100 is thinned continuously all around the chip 180b by means of the formation of the trench 140b. Later singulation can then be carried out along this prepared trench 140b, for example by means of etching and/or laser cutting and/or, given sufficient thinness of the residual wafer 100 in the region of the trench 140b, by breaking.

FIG. 1B shows, in an illustration similar to FIG. 1A, a second wafer 101 (upper and lower subfigures), likewise having a first surface 101a and a second surface 101b, with once again a lateral illustration of a detail from the exemplary protective device 120 according to the invention from FIG. 1A with respect to a plane A. Like the wafer 100, the wafer 101 has open MEMS structures 131 on the first surface 101a, which are provided for chips 181. Zones 141 provided for a subsequent etching process for singulating the wafer 101 (etching structures) are identified in FIG. 1B. As can be seen in the lower subfigure, these etching structures 141 only partly penetrate through the wafer. These etching structures 141 are likewise depicted in the upper subfigure for the sake of better clarity, even though these etching structures 141, as evident from the lower subfigure, are not visible in a view of the first surface 100a.

Furthermore, recesses 151 are manifested in the wafer 101, which recesses for example may have been produced by preceding etching processes and constitute trenches which enclose the individual chips 181. The totality of these trenches 151 thus constitutes a trench structure enclosing the individual chips 181 within the meaning of the invention. In contrast to the chip 181 in FIG. 1A, here a trench structure was manifested on the first surface 100a. The recesses 151 have an L-shaped form realized by corresponding undercuts 160 in the wafer 101. These undercuts 160 serve as holding structures. If the wafer is singulated by etching in the region of the etching structures 141 along the trench structure formed by the recesses 151 (or some other method is used to remove the material of the wafer in these regions for singulating), the chips 181 are separated from one another and from the rest of the wafer 106. The individual chips 181 first fall vertically downwards, illustrated by arrows 190 in FIG. 1B (if the protective device 120 shown and the wafer 101 are oriented perpendicularly to the direction of gravity), but are then braked by the holding structures, as illustrated in FIG. 1C. In contrast to what is shown in FIGS. 1B and 1C, such holding structures can also be embodied only locally, i.e. need not be present at every point of a trench or of a gap.

FIG. 1C shows the wafer 101 and the protective device 120 according to the invention from FIG. 1B after singulation of the wafer 101 by removal of the etching structures 141, which have now been replaced by cavities 142. As per the etching structures 141 in FIG. 1B, the cavities 142 are depicted here for the sake of better clarity, which cavities are actually not visible in a view of the surface 100a of the wafer 100.

As illustrated, the projections 185 on the chips 181, said projections being realized by the recesses 151 in the wafer 101, ensure that the movement 190 of the individual chips 181 downwards is stopped since these projections 185 get caught on residual parts 106a of the rest of the wafer 106. This prevents a situation in which the chips 181 impinge on a base, for example of the protective device 120, after singulation with the open MEMS structures 131, which might lead to damage to the open MEMS structures 131. After singulation, however, the chips 181 can be removed (arrows 195) from the protective device 120 upwards (i.e. opposite to the direction of gravity and thus the direction of the arrows 190), for example by means of a suitable removal device 192, which can be vacuum-based. After singulation and removal of the individual chips from the protective device, the projections 185 can be completely removed in a further step, for example mechanically and/or by means of laser cutting and/or an etching method.

The procedures from FIG. 1A can furthermore also be combined with the procedure from FIGS. 1B and 1C in order to prevent the individual chips 180a, 180b from undesirably falling out and/or falling down after singulation if the chips 180a, 180b are not removed from the protective device 120 directly with the singulation.

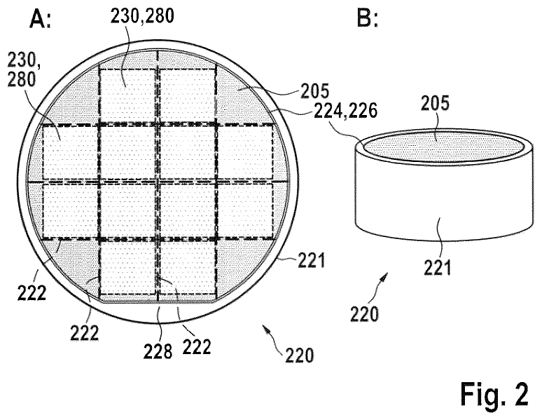

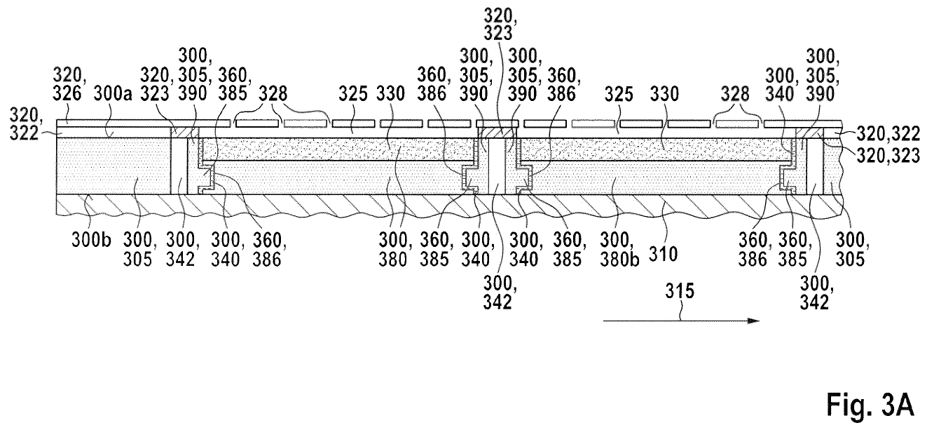

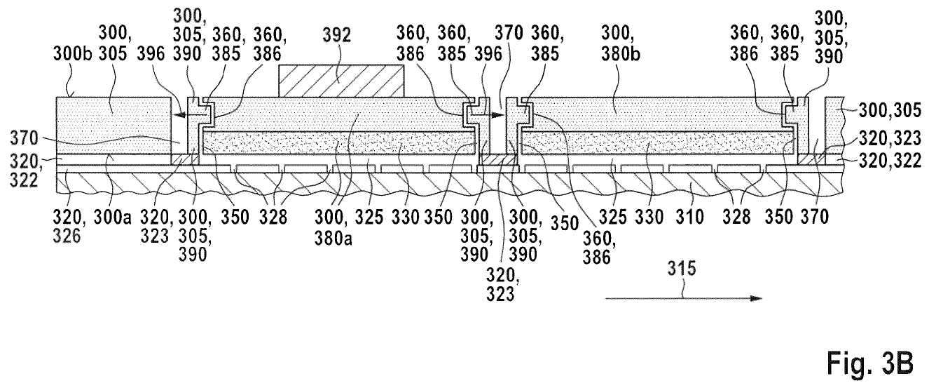

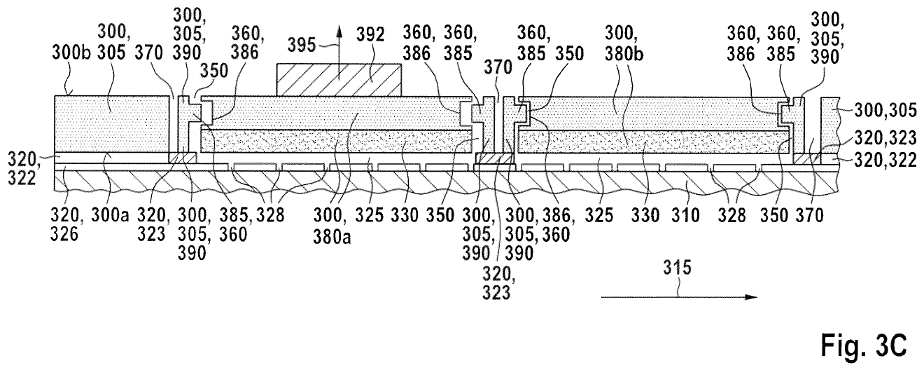

FIG. 2 shows a schematic illustration of a further wafer 200 in a further exemplary protective device 220 according to the invention in a plan view (subfigure A) and in a perspective view (subfigure B). The wafer 200 has MEMS structures 230 (only illustrated in subfigure A) situated on twelve chips 280 to be produced. In subfigure A, these MEMS structures 230 are situated on that surface of the wafer 200 which faces away from an observer of FIG. 2 and is not illustrated, which is why the corresponding squares representing MEMS structures 230 are provided with dashed edges. The same applies to the carrying structures 222 of the protective device 220, which are likewise illustrated as dashed lines and symbolize continuous walls below the wafer 200. It is advantageous for a protective device 220 if the latter has a wall 221 laterally closing off the protective device 220 in order to protect the downwardly directed surface of the wafer 220 against damage and contamination. The protective device 220 furthermore has a fixing element 224, which consists of a frame 226 enclosing the wafer 220. This frame prevents the wafer 220 from being undesirably laterally displaced. The fixing element 224 is advantageously furthermore shaped such that a notch or flat 228 (not illustrated in subfigure B) of the wafer 220 is used to achieve a desired orientation during positioning of the wafer 220 on the protective device 220 (during contacting of the wafer 220 with the protective device 220). For this purpose, for example, the frame 226 can be provided with a corresponding protuberance 228 (not illustrated in subfigure B). FIGS. 3A, 3B and 3C show three schematic illustrations of a detail from a further exemplary protective device according to the invention with a third wafer after different steps of a method according to the invention. All three figures are in the form of a side view. In this embodiment of the invention, a gap structure is used for singulation.

FIG. 3A shows an exemplary protective device 320 according to the invention having carrying structures 322, which is in contact with a wafer 300 having two surfaces 300a and 300b. The wafer 300 is situated on a repository 310. Two chips 380a, 380b to be produced are illustrated by way of example, which have open MEMS structures 330. These open MEMS structures 330 are directed upwards. The protective device 320 was positioned on the wafer 300 such that the first surface 300a of the wafer is in contact with the carrying structures 322, the carrying structures 322 not touching the open MEMS structures 330. In order to avoid undesired displacements of wafer and protective device with respect to one another and to enable later rotation of the protective device with the wafer, the protective device was bonded to the wafer.

The wafer 300 has etching structures 340 in each case on the left and right of a chip 380a, 380b to be produced, which etching structures delimit the chips 380a, 380b. These etching structures 340 serve for forming a gap structure which allows the wafer 330 to be singulated. At the same time, holding structures 360 are intended to be manifested by an etching process, these future holding structures 360 comprising laterally positioned grooves 386 in the chips 380a, 380b and matchingly arranged projections in adjoining wafer portions 390 of the rest of the wafer 305. The holding structures 360 are locally delimited, that is to say that they do not run along the complete etching structures 340. FIGS. 3A, 3B, 3C each show a sectional plane running precisely through the holding structures 360. Recesses 323 are situated in the regions lying below the wafer portions 390 with the projections 385 in order to enable mobility of the wafer portions 390 with the projections 385 after an etching process for etching the etching structures 340. The carrying structures 322 are thus exposed in the region of the wafer portions 390. In order to enable mobility of the projections 385 and the wafer portions 390 associated therewith, further etching structures 342 are situated in the region of these wafer portions 390. The wafer portions 390 of the wafer 300 which are situated between the etching structures 340 and 342 are movable after the etching process has been carried out, and can be configured as spring elements, for example.

Furthermore, holes 328 that serve for supplying an etching gas are situated in a rear-side outer wall 326 of the protective device 320. For this purpose, the protective device 320 together with the wafer 300 is positioned in an environment filled with the etching gas. The etching gas penetrates through the holes 328 into the interior 325 of the protective device 328; the etching structures 340 and the further etching structures 342 are etched. In this case, the etching gas can reach the further etching structures 342 via the recesses 323. At the same time, the etching gas guided into the interior 325 can be used for example to implement sacrificial layer etching and thereby to free the MEMS structures 330. Only twelve holes 328 are shown in each of FIGS. 3A, 3B and 3C, for the sake of better clarity, wherein this number is purely by way of example and can also be significantly higher. Moreover, the holes 328 are not depicted in a manner true to scale in the figures. The holes 328 typically have a diameter chosen such that undesirable foreign particles, starting from a specific size, cannot pass into the interior 325 from the environment.

FIG. 3B shows the exemplary protective device 320 according to the invention from FIG. 3A with the corresponding wafer 300 after an etching process has been carried out by an etching gas being supplied through the holes 328. By means of the etching gas, the etching structures 340 were removed and this resulted in the formation of a gap structure having gaps 350 in the wafer 300, as a result of which the wafer 300 was singulated. The MEMS structures 330 of the chips 380a, 380b were likewise freed by means of the etching gas, identified in FIG. 3B by a different pictorial illustration of the regions of the MEMS structures 330 in comparison with FIG. 3A. Furthermore, the protective device with the wafer was rotated by 180° about an axis of rotation 315, which runs parallel to the first surface 300a of the wafer 300, and after the rotation was positioned again on the repository 310, which now blocks the holes 328. Accordingly, it is no longer possible for the etching gas to be supplied via the holes 328. The rotating was effected after the etching process. Holding structures 360 having the projections 385 and grooves 386 interlocked therewith, which are manifested as a result of the etching process, hold the chips 380a, 380b in the wafer 300 after singulation by means of these projections 385 and grooves 386; the chips 380a, 380b cannot move freely upwards or downwards. Consequently, the wafer with the protective device can be rotated without the risk of the chips 380a, 380b falling out.

A removal device 392, which can be vacuum-based, for example, was positioned above the left chip 380a, and temporarily fixes the chip 380a. In order that this chip 380a can now be removed, the wafer portions 390 having the projections 385 are moved away from the grooves 386 of the chip 308a (arrows 396). Such movements in the directions 396 are made possible by virtue of the fact that cutouts 370 have been etched free in the wafer 300 in the movement direction 396 in accordance with the further etching structures 342 by means of the etching process. The now movable wafer portions 390 having the projections 385 can for example be configured as spring elements and be moved away from the chip 380a by a suitable tool (not illustrated). In this case, the chip 380a is held continuously by the removal device in order to prevent the chip 380a from falling down.

FIG. 3C shows the situation after movement of the wafer portions 390 having the projections 385 in the directions 396, the projections 385 now being situated completely outside the grooves 386. The chip 380a is thus now movable downwards and upwards independently of the rest of the wafer 305, but is still fixed by the removal device 392 and can now be removed with the latter from the wafer 300 upwards (arrow 395). A procedure identical to that illustrated in FIGS. 3B and 3C is also possible for the further chips of the wafer 300, such as the chip 380b.

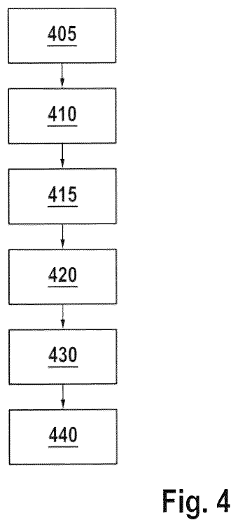

Finally, FIG. 4 shows, in schematic form as a flow diagram, a method according to the invention for singulating a wafer 100, 101, 200 using a protective device 120, 220 according to the invention, wherein the wafer 100, 101, 200 has a first surface 100a, 101a and a second surface 100b, 101b, wherein structures to be protected, for example MEMS structures 130, 131, 230, are situated on the first surface 100a, 101a of the wafer 100, 101, 200.

The wafer 100, 101, 200 is contacted with a protective device 120, 220 according to the invention (step 410), for example is positioned thereon, specifically such that the first surface 100a, 101a of the wafer 100, 101, 200 is in contact with carrying structures 122, 222 of the protective device 120, 220. A typical protective device 120, 220 according to the invention holds the wafer 100, 101, 200 counter to the direction of gravity, the wafer 100, 101, 200 bears on the carrying structures 122, 222, and the first surface 100a, 101a of the wafer 100, 101, 200 faces downwards (in the direction of gravity). The protective device 120, 220 protects the surface having the structures to be protected, i.e. the first surface 100a, 101a, of the wafer 100, 101, 200 against contamination by foreign particles and other damage.

The wafer 100, 101, 200 can then be processed as desired. In particular, after positioning the wafer 100, 101, 200 on the protective device 120, 220, it is possible for the wafer 100, 101, 200 to be provided with a gap structure, a locally perforating gap structure 140a and/or a trench structure 140b (step 415), for example by means of etching processes. Such a gap structure and/or locally perforating gap structure and/or trench structure 140a, 140b can later serve for the singulation of the wafer 100, 101, 200 into individual chips 180a, 180b, 181, 280. Alternatively or additionally, such structures can also be formed before contacting 410 the wafer with the protective device 120, 220 (step 405).

After contacting 410 the wafer with the protective device, it is also possible to effect further processing steps 420, for example to carry out soldering and/or sintering processes and/or to apply the corresponding solders and/or sintering pastes, for example by printing. In particular, wafer bonding with a further wafer can be effected in order to produce a coupled wafer. Moreover, a wafer test of the wafer 100, 101, 200 and/or of the future chips 180a, 180b, 181, 280 can be carried out. Finally, singulating 430 the wafer 100, 101, 200 is effected, wherein in the case of a wafer 100, 101, 200 correspondingly prepared by way of gap and/or trench structures 140a, 140b, the singulating 430 is preferably effected by mechanical breaking and/or laser cutting. Here for example in the case of singulating 430 by means of breaking, removing 440 can be effected in parallel with the singulating 430. By way of example, for this purpose, the chips 180a, 180b, 181, 280 are broken out from the wafer 100, 101, 200. In the case where the chips 180a, 180b, 181, 280 remain in the protective device 120, 220 after the singulating 430, advantageously in a manner held by corresponding holding structures, the chips 180a, 180b, 181, 280 can also be tested for their correct functionality at this point in time in the protective device 120, 220 before their removing 440.

The invention is not limited to the exemplary embodiments described here and the aspects highlighted therein. On the contrary, a large number of modifications that are within the ability of a person skilled in the art are possible within the scope specified by the claims.

1. A method for singulating a wafer, including a first surface and a second surface situated opposite the first surface comprising the following steps:
a. contacting the wafer with a protective device including one or a plurality of carrying structures such that the first surface of the wafer is in contact with the one or the plurality of carrying structures;
b. singulating the wafer that is in contact with the protective device into a plurality of chips; and
c. removing the chips from the wafer that is in contact with the protective device.

2. The method according to claim 1, wherein after contacting the wafer with the protective device and before or with singulating the wafer, the method further comprises:
forming, a gap structure which encloses individual and comprises one or a plurality of gaps in the wafer is effected, and the singulating is effected at least partly by forming the gap structure; and/or
forming a gap structure which encloses individual chips locally perforates the wafer and comprises a plurality of gaps in the wafer is effected, and the singulating is effected at least partly along these plurality of gaps; and/or
forming a trench structure which encloses individual chips and comprises one or a plurality of trenches on the first surface and/or the second surface of the wafer is effected, and the singulating is effected at least partly along the one or the plurality of trenches.

3. The method according to claim 2, wherein forming the gaps and/or the trenches is effected by means of an etching process.

4. The method according to claim 3, wherein the etching process additionally serves for etching structures of the chips.

5. The method according to claim 1, wherein the singulating is carried out using an etching method, a laser cutting method and/or a breaking method.

6. The method according to claim 1, wherein the wafer comprises open MEMS structures for microelectromechanical systems.

7. The method according to claim 6, wherein the open MEMS structures are open towards the first surface of the wafer and the wafer is contacted with the protective device such that the one or the plurality of carrying structures do not touch the open MEMS structures.

8. The method according to claim 6, wherein the open MEMS structures comprise MEMS structures for a micromirror array.

9. The method according to claim 1, wherein the wafer comprises holding structures, and/or after contacting with the protective device and before singulating the wafer, forming holding structures in the wafer is effected, wherein the holding structures are configured to restrict possible movements of the chips after singulating in at least one direction.

10. The method according to claim 9, wherein the wafer is connected to the protective device and, after singulating and before removing the chips, is rotated together with the protective device by an angle of 170° to 190° about an axis parallel to the first surface of the wafer, and the holding structures are manifested such that the chips remain in the wafer during the rotating and the wafer is connected to the protective device.

11. The method according to claim 10, wherein the protective device is arranged above the wafer before the rotating.

12. The method according to claim 1, wherein singulating the wafer is effected with removing the chips from the protective device.

13. A protective device including one or a plurality of carrying structures for temporarily carrying a wafer on the protective device and/or for temporarily carrying the protective device on the wafer, wherein the protective device is configured to be used in a method according to claim 1.

14. The protective device according to claim 13, wherein the protective device comprises a fixing device for temporarily fixing the wafer, wherein the fixing device includes one or a plurality of fixing elements for preventing an undesired lateral displacement of the wafer.

15. The protective device according to Claim 13, wherein the protective device comprises an outer wall comprising an opening for gas supply.
